(19) United States
(12) Patent Application Publication
(10) Pub. No.: US 2004/0142525 A1
(43) Pub. Date: Jul. 22, 2004

(54) Method of manufacturing a semiconductor device

(76) Inventor: Seok Su Kim, Gyeonggi-do (KR)

Correspondence Address: GROSSMAN & FLIGHT LLC, Suite 4220, 20 North Wacker Drive, Chicago, IL, 60606-6357, US

(21) Appl. No.: 10/746,799

(22) Filed: Dec. 26, 2003

(30) Foreign Application Priority Data
Dec. 30, 2002 (JP) 10-2002-0087303

(51) Int. Cl. H01L 21/336

(52) U.S. Cl. 438/198

(57) ABSTRACT

A method for fabricating a semiconductor device is disclosed. An example method provides a semiconductor substrate and forms a first gate electrode comprising a gate oxide, a first conducting layer pattern, and an insulating layer pattern, wherein the first gate electrode is configured to function as a normal gate electrode. The example method forms spacers on sidewalls of the first gate electrode, and forms a dielectric layer on the semiconductor substrate except in the region of the first gate electrode and the spacers. In addition, the example method forms a second conducting layer over the dielectric layer, the spacers, and the first gate electrode, and forms a second gate electrode comprising a second conducting layer pattern and a dielectric layer pattern by removing some parts of the dielectric layer and the second conducting layer through an etching process. The second gate electrode is configured to function as a flash memory.

### FIELD OF THE DISCLOSURE

The present disclosure relates generally to semiconductor devices and, more particularly, to a McRAM device that includes a first gate electrode that functions as a flash memory and a second gate electrode that functions as a normal gate electrode formed on a single substrate.

### BACKGROUND

With the rapid spread of intelligent devices such as computers, semiconductor devices are rapidly being developed. Semiconductor devices are commonly required to have high storage-capability as well as to operate with high speed. To meet these requirements, technologies for manufacturing semiconductor devices are being developed to improve the degree of integration, reliability, and a response rate of semiconductor devices.

Generally, semiconductor memory devices are divided into volatile and nonvolatile memory devices. Examples of nonvolatile memory devices include a flash memory device, a McRAM device, etc. A McRAM device includes a first gate electrode that functions as a flash memory and a second gate electrode that functions as a normal gate electrode in a single cell. Recently, McRAM devices have become popular due to their advantages such as low power dissipation, low manufacturing cost, and rapid speed of information processing.

FIGS. 1a through 1c illustrate, in cross-sectional views, the process steps for fabricating a McRAM device according to a conventional method. Referring to FIG. 1a, a substrate 1 including an active region 2 and a non-active region 3 is provided. A dielectric layer 5, a first conducting layer 7, and an insulating layer 9 are deposited in sequence over the substrate 1. A mask layer 10 is formed on the insulating layer 9.

Referring to FIG. 1b, an etching process is performed using the mask layer 10 as an etching mask. As a result, a first gate electrode 11 comprising a dielectric layer pattern 5a, a first conducting layer pattern 7a, and an insulating layer pattern 9a is formed on the active region 2 of the substrate 1. The first gate electrode 11 functions as a flash memory. After the formation of the first gate electrode 11, spacers 12 are formed on sidewalls of the first gate electrode 11.

Referring to FIG. 1c, an oxide layer 13 is formed on the substrate 1 except the region of the first gate electrode 11 and the spacers 12. A second conducting layer 15 is formed over the oxide layer 13, the first gate electrode 11, and the spacers 12. A mask pattern 20 is formed on the second conducting layer 15.

Referring to FIG. 1d, an etching process is performed using the mask pattern 20 as an etching mask to form a second conducting layer pattern 15a and a gate oxide 13a. Then, the mask pattern 20 is removed. As a result, a second gate electrode 17 comprising the second conducting layer pattern 15a and the gate oxide 13a is formed on the active region 2 of the substrate 1. The second gate electrode 17 functions as a normal gate electrode.

Here, if a residual dielectric layer (not shown) remains on the substrate 1 after the formation of the first gate electrode 11, it has to be removed completely because, in the following process, the second gate electrode 17 has to be formed on the substrate 1. However, when the residual dielectric layer is removed, the substrate 1 may be damaged, which may cause defects such as voids under the spacers 12, thereby deteriorating device reliability.

To obviate deterioration of device reliability due to the damage caused by etching in fabricating a semiconductor device, U.S. Pat. No. 6,465,841, Hsieh et al., discloses a method of forming a split-gate flash memory cell having nitride spacers formed on a pad oxide and prior to the forming of an inter-poly oxide layer thereover. In this method, any damage that would normally occur to the inter-poly oxide during the etching of the nitride spacers subsequent to the forming of the inter-poly oxide is avoided. Accordingly, the variation in the thickness of the inter-poly oxide duet to the unpredictable damage to the underlying spacers is also avoided by reversing the order in which the spacers and the inter-poly oxide are formed, including the forming of the pad oxide first.

As another example, Japanese Patent Publication No. 2002-151606, Ri et al., discloses a technique that prevents damage of a floating gate electrode which is to be caused by etching without deteriorating reliability of a dielectric film. In this Japanese patent publication, a protective film composed of material excellent in an etching selection ratio to an element isolation film and a doped polysilicon film is formed on an upper surface of the doped polysilicon film forming a floating gate electrode. Then, a part of the protective film is etched, and a recess is contained in the protective film. After that, a substance film for forming spacers which is composed of material excellent in an etching selection ratio of the element isolation film to the doped polysilicon film is formed on an upper surface of the protective film. An etch-back process is performed and spacers are formed. At this time, by the protective film containing the recess, the doped polysilicon film is prevented from damage, which is to be caused by etching.

### BRIEF DESCRIPTION OF THE DRAWINGS

Figs. FIGS. 1a through 1d illustrate, in cross-sectional views, an example method for fabricating a McRAM device according to a conventional method.

FIGS. 2a through 2d illustrate, in cross-sectional views, an example for fabricating an example semiconductor device.

### DETAILED DESCRIPTION

As described in greater detail below, a method of manufacturing a semiconductor device includes a method of forming a first gate electrode that functions as a normal gate electrode and a second gate electrode that functions as a flash gate in a single cell without damaging a substrate in fabricating a semiconductor device.

In one example method for manufacturing or fabricating a semiconductor device, a substrate including an active region and a non-active region is provided and a first gate electrode comprising a gate oxide, a first conducting layer pattern, and an insulating layer pattern, the first gate electrode functioning as a normal gate electrode is formed. The example method may also form spacers on sidewalls of the first gate electrode, form a dielectric layer on the substrate except the region of the first gate electrode and the spacers, form a second conducting layer over the dielectric layer, the spacers, and the first gate electrode, and form a second gate electrode comprising a second conducting layer pattern and a dielectric layer pattern by removing some parts of the dielectric layer and the second conducting layer through an etching process, the second gate electrode functioning as a flash memory.

During the formation of the second gate electrode, the dielectric layer need not be completely removed. In other words, a residual dielectric layer may remain on the substrate after the formation of the second gate electrode. Therefore, the present invention can protect the substrate from etching by leaving the residual dielectric layer on the substrate.

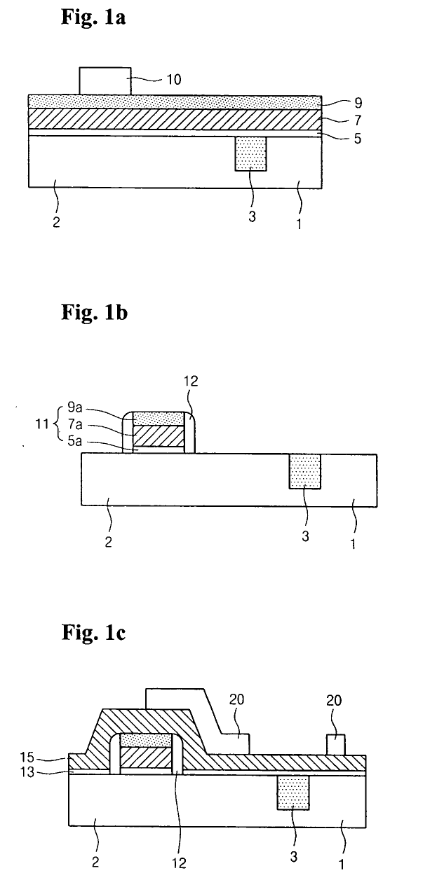

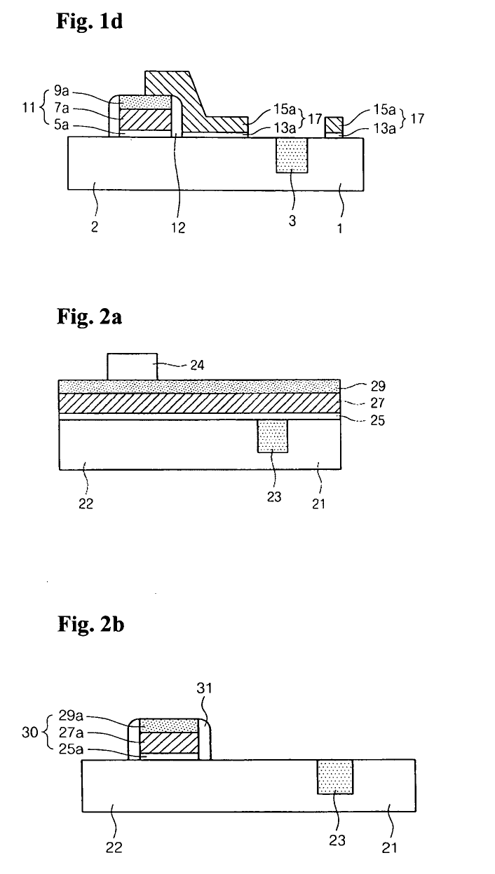

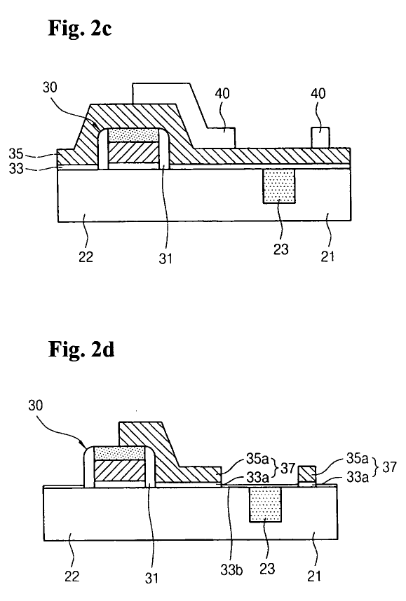

Referring to FIG. 2a, a substrate 21 including an active region 22 and a non-active region 23 is provided. The non-active region 23 preferably has a trench structure. An oxide layer 25, a first conducting layer 27, and an insulating layer 29 are deposited in sequence on the substrate 21. The first conducting layer 27 is preferably polysilicon. The insulating layer is preferably oxide or nitride. Then, a mask layer 24, preferably a photoresist pattern, is formed on the insulating layer 29 by photolithography.

Referring to FIG. 2b, an etching process is performed using the mask layer 24 as an etching mask. Thus, some parts of the insulating layer 29, the first conducting layer 27, and the oxide layer 25 are removed in sequence to form an insulating layer pattern 29a, a first conducting layer pattern 27a, and an a gate oxide 25a, respectively. Then, the mask layer 24 is removed. As a result, a first gate electrode 30 comprising the gate oxide 25a, the first conducting layer pattern 27a, and the insulating layer pattern 29a is formed on the active region 22 of the substrate 21. The first gate electrode functions as a normal gate electrode.

Next, a thin layer is deposited over the substrate 21 including the first gate electrode 30. The thin layer is removed by an etch back process to form spacers 31 on sidewalls of the first gate electrode 30.

Referring to FIG. 2c, a dielectric layer 33 is formed on the substrate except the region of the first gate electrode 30 and the spacers 31. Then, a second conducting layer 35 is formed over the dielectric layer 33, the first gate electrode 30, and the spacers 31. The second conducting layer 35 is preferably polysilicon because the second conducting layer is preferably formed of the same material with the first conducting layer 27. Next, a mask layer 40, preferably a photoresist pattern, is formed on the second conducting layer 35 by photolithography.

Referring to FIG. 2d, an etching process is performed using the mask layer 40 as an etching mask. Thus, some parts of the second conducting layer 35 and the dielectric layer 33 are removed in sequence to form a second conducting layer pattern 35a and a dielectric layer pattern 33a. Then, the mask layer 40 is removed. As a result, a second gate electrode 37 comprising the second conducting layer pattern 35a and the dielectric layer pattern 33a is formed on the active region 22 of the substrate 21. The second gate electrode 37 functions as a flash memory.

Here, during the etching process for the formation of the second gate electrode, the dielectric layer 33 need not be completely removed. In other words, a residual dielectric layer 33b may remain on the substrate after the etching process. Therefore, the substrate can be protected from the etching due to the residual dielectric layer 33b.

The example method described herein can prevent the substrate from being damaged during the etching process, thereby reducing occurrences of defects due to etching. Accordingly, the example method disclosed herein can improve device reliability in fabricating a semiconductor device.

Although certain methods and apparatus have been described herein, the scope of coverage of this patent is not limited thereto. To the contrary, this patent covers all embodiments fairly falling within the scope of the appended claims either literally or under the doctrine of equivalents.

What is claimed is:

1. A method for fabricating a semiconductor device comprising:
providing a semiconductor substrate;
forming a first gate electrode comprising a gate oxide, a first conducting layer pattern, and an insulating layer pattern, wherein the first gate electrode is configured to function as a normal gate electrode;
forming spacers on sidewalls of the first gate electrode;
forming a dielectric layer on the semiconductor substrate except the region of the first gate electrode and the spacers;
forming a second conducting layer over the dielectric layer, the spacers, and the first gate electrode; and
forming a second gate electrode comprising a second conducting layer pattern and a dielectric layer pattern by removing some parts of the dielectric layer and the second conducting layer through an etching process, the second gate electrode configured to function as a flash memory.

2. The method as defined by claim 1, wherein the insulating layer pattern is formed of oxide or nitride.

3. The method as defined by claim 1, wherein the first and second conducting layer patterns are formed of same material.

4. The method as defined by claim 3, wherein the same material is polysilicon.
